(19) United States
(12) Patent Application Publication
(10) Pub. No.: US 2024/0397734 A1
(43) Pub. Date: Nov. 28, 2024

(54) SEMICONDUCTOR DEVICE AND METHOD FOR FABRICATING THE SAME

(71) Applicant: SK hynix Inc., Icheon-si (KR)

(72) Inventors: Jeong Myeong KIM, Icheon-si (KR); Cha Deok DONG, Icheon-si (KR); Keo Rock CHOI, Icheon-si (KR)

(21) Appl. No.: 18/393,555

(22) Filed: Dec. 21, 2023

(30) Foreign Application Priority Data
May 26, 2023 (KR) 10-2023-0068390

(51) Int. Cl. H10B 63/00; H01L 21/3115; H01L 23/528; H10B 53/00; H10B 61/00; H10B 63/10

(52) U.S. Cl. CPC H10B 63/80; H01L 21/31155; H01L 23/528; H10B 53/00; H10B 61/00; H10B 63/10

(57) ABSTRACT

A semiconductor device includes a plurality of memory cells. Each memory cell includes: a memory layer configured to store data; and a selector layer configured to control an access to the memory layer, wherein the selector layer includes a layer which includes an insulating material and a porous material that are mixed, and a dopant that is present in the layer and breaks a bond between constituent elements of the insulating material.

### PRIORITY CLAIM AND CROSS-REFERENCE TO RELATED APPLICATION

This patent document claims priority under 35 U.S.C. § 119 to Korean Patent Application No. 10-2023-0068390 filed on May 26, 2023,which is incorporated herein by reference in its entirety.

### TECHNICAL FIELD

This patent document relates to a semiconductor technology, and more particularly, to a semiconductor device including a memory cell including a selector, and a method for fabricating the semiconductor device.

### BACKGROUND

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor devices which can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

In an embodiment, a semiconductor device may include a plurality of memory cells, wherein each memory cell comprises: a memory layer configured to store data; and a selector layer configured to control an access to the memory layer, wherein the selector layer includes a layer which includes an insulating material and a porous material that are mixed, and a dopant that is present in the layer and breaks a bond between constituent elements of the insulating material.

In an embodiment, a method for fabricating a semiconductor device, may include: forming a memory layer configured to store data; and forming a selector layer for controlling an access to the memory layer, wherein the forming of the selector layer comprises: forming a porous layer; forming an insulating layer over the porous layer; and performing an ion implantation to implant a dopant into the porous layer and the insulating layer, wherein the dopant is capable of breaking a bond between constituent elements of the insulating layer.

In an embodiment, a method for fabricating a semiconductor device, may include: forming a memory layer configured to store data; and forming a selector layer for controlling an access to the memory layer, wherein the forming of the selector layer comprises: forming a porous layer; performing a first ion implantation to implant a first dopant into the porous layer; forming an insulating layer over the porous layer; and performing a second ion implantation to implant a second dopant into the porous layer and the insulating layer, wherein the first and second dopants are capable of breaking a bond between constituent elements of the insulating layer.

### BRIEF DESCRIPTION OF THE DRAWINGS

FIG. 1 is a perspective view illustrating a semiconductor device according to an embodiment of the present disclosure.

FIGS. 2A and 2B are cross-sectional views illustrating a selector layer and a method for forming the same according to a first embodiment of the present disclosure.

FIGS. 3A to 3D are cross-sectional views illustrating a method for forming a selector layer according to a second embodiment of the present disclosure.

FIG. 4 is a view illustrating a content of constituent elements of a selector layer.

FIG. 5 is a view illustrating a characteristic of a selector layer.

FIG. 6 is a view illustrating a half current according to a threshold voltage of a selector layer.

FIG. 7 is a photograph illustrating arsenic distribution in a selector layer.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers).

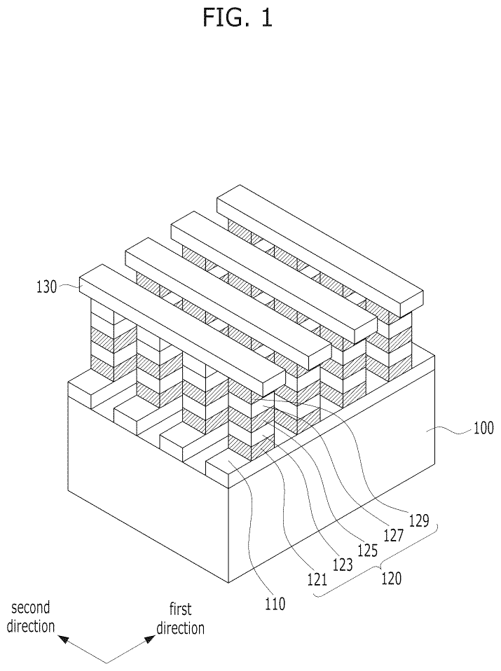

FIG. 1 is a perspective view illustrating a semiconductor device according to an embodiment of the present disclosure.

Referring to FIG. 1, the semiconductor device according to the present embodiment may include a substrate 100, a plurality of first conductive lines 110 disposed over the substrate 100 and extending in a first direction to be parallel to each other, a plurality of second conductive lines 130 disposed over the first conductive lines 110 and extending in a second direction intersecting the first direction to be parallel to each other, and a plurality of memory cells 120 interposed between the first conductive lines 110 and the second conductive lines 130 and respectively disposed to overlap intersection regions of the first conductive lines 110 and the second conductive lines 130.

The substrate 100 may include a semiconductor material such as silicon. In some implementations, the substrate 100 may include additional structures (not shown), for example, an integrated circuit for driving the first conductive lines 110 and/or the second conductive lines 130.

The first conductive line 110 and the second conductive line 130 may be connected to both ends of the memory cell 120, respectively. One of the first conductive line 110 and the second conductive line 130 may function as a word line and the other may function as a bit line. Each of the first conductive line 110 and the second conductive line 130 may include various conductive materials, for example, a metal such as platinum (Pt), tungsten (W), aluminum (Al), copper (Cu), tantalum (Ta), or titanium (Ti), a metal nitride such as titanium nitride (TiN), tantalum nitride (TaN), or tungsten nitride (WN), or a combination thereof.

The memory cell 120 may be in various suitable shapes. In some implementations, the memory cell 120 may have a pillar shape and disposed between the first conductive line 110 and the second conductive line 130 so as to overlap an intersection region of the first conductive line 110 and the second conductive line 130. In an example, the memory cell 120 may have a square pillar shape having sidewalls in the first direction and sidewalls in the second direction. The sidewalls of the memory cell 120, which are in the first direction, are aligned with sidewalls of the second conductive line 130 and the sidewalls of the memory cell 120, which are in the second direction, are aligned with sidewalls of the first conductive line 110. However, the present disclosure is not limited thereto, and the planar shape of the memory cell 120 may be variously modified. For example, the memory cell 120 can have a circular, elliptical, or polygonal shape as long as the memory cell 120 overlaps the intersection area of the first conductive line 110 and the second conductive line 130.

The memory cell 120 may include a first electrode layer 121, a selector layer 123, a second electrode layer 125, a memory layer 127, and a third electrode layer 129.

The first electrode layer 121 and the third electrode layer 129 may be positioned at the bottom and top of the memory cell 120, respectively, and may function as a passage through which a voltage or current passes. The second electrode layer 125 may function as a passage through which a voltage or current passes between the selector layer 123 and the memory layer 127 by electrically connecting the selector layer 123 and the memory layer 127 while physically separating the selector layer 123 and the memory layer 127. Each of the first electrode layer 121, the second electrode layer 125, and the third electrode layer 129 may include various conductive materials, for example, a metal such as platinum (Pt), tungsten (W), aluminum (Al), copper (Cu), tantalum (Ta), or titanium (Ti), a metal nitride such as titanium nitride (TiN), tantalum nitride (TaN), or tungsten nitride (WN), or a combination thereof.

The memory layer 127 may function to store data in various ways. In an example, the memory layer 127 may include a variable resistance layer that stores different data by being in different resistance states and by switching between different resistance states according to a voltage or current supplied through upper and lower ends of the memory layer 127. The variable resistance layer may have a single-layer structure or a multi-layer structure including various materials used in RRAM, PRAM, FRAM, MRAM, etc., for example, a metal oxide such as a transition metal oxide or a perovskite-based material, a phase change material such as a chalcogenide-based material, a ferroelectric material, a ferromagnetic material, or others.

The selector layer 123 may control access to the memory layer 127 while preventing or reducing current leakage that may occur between the memory cells 120 sharing the first conductive line 110 or the second conductive line 130. In some implementations, the selector layer 123 is a layer that is structured to be operated to function as a current control layer capable of controlling the current flow through the layer in response to an applied voltage and can be used in various semiconductor devices. In some implementations, the selector layer 123 may have a threshold switching characteristic in which a current is blocked or hardly flows when the magnitude of the voltage supplied to the selector layer 123 is less than a predetermined threshold voltage, and the passage of the current rapidly increases at a voltage equal to or higher than the threshold voltage. Thus, the selector layer 123 may be turned on above the threshold voltage and turned off below the threshold voltage. This threshold value may be referred to as a threshold voltage, and the selector layer may be controlled to be in either a turned-on or “on” state to be electrically conductive or a turned-off or “off” state to be electrically less-conductive than the “on” state or electrically non-conductive depending on whether the applied voltage is above or below the threshold voltage. Thus, the selector layer exhibits different electrically conductive states to provide a switching operation to switch between the different electrically conductive states by controlling the applied voltage relative to the threshold voltage.

The selector layer 123 may include at least one of a diode, an OTS (Ovonic Threshold Switching) material such as a chalcogenide-based material, an MIEC (Mixed Ionic Electronic Conducting) material such as a metal-containing chalcogenide-based material, an MIT (Metal Insulator Transition) material such as NbO₂ or VO₂, or a tunneling insulating material having a relatively wide band gap, such as SiO₂ or Al₂O₃.

In some implementations, the selector layer 123 may include an insulating layer doped with dopants. The insulating layer may include a silicon-containing insulating material such as silicon oxide, silicon nitride, or silicon oxynitride, an insulating metal oxide, an insulating metal nitride, or a combination thereof. The dopants may serve to create trap sites that capture conductive carriers moving in the insulating layer or provide a passage through which the captured conductive carriers move again. To form the trap sites, various elements capable of generating an energy level capable of accommodating the conductive carriers in the insulating layer may be used as the dopant. In an example, when the insulating layer contains silicon, the dopants may include a metal having a valence different from that of silicon, such as gallium (Ga), boron (B), indium (In), phosphorus (P), arsenic (As), antimony (Sb), germanium (Ge), carbon (C), tungsten (W), or a combination thereof. Alternatively, when the insulating layer contains a metal, the dopants may include a metal having a valence different from that of the metal, silicon, or others. In an example, the selector layer 123 may include silicon dioxide (SiO₂) doped with arsenic (As). When a voltage higher than the threshold voltage is applied to the selector layer 123 including the insulating layer doped with the dopants, the conductive carriers may move through the trap sites, and thus, a turned-on state in which a current flows through the selector layer 123 may be implemented. When the voltage applied to the selector layer 123 is reduced below the threshold voltage, the conductive carriers may not move, and thus, a turned-off state in which no current flows may be implemented.

In this embodiment, the memory cell 120 includes a stacked structure of the first electrode layer 121, the selector layer 123, the second electrode layer 125, the memory layer 127, and the third electrode layer 129, but the present disclosure is not limited thereto. The layer structure of the memory cell 120 may be variously modified.

In an example, at least one of the first electrode layer 121, the second electrode layer 125, and the third electrode layer 129 may be omitted. In some implementations, the upper and lower positions of the selector layer 123 and the memory layer 127 may be reversed with each other. In some implementations, the memory cell 120 may further include one or more layers (not shown) to improve characteristics or process.

When the selector layer 123 includes an insulating layer doped with dopants, the selector layer 123 may be formed by depositing the insulating layer and implanting ions into the insulating layer. When the insulating layer includes a material having a very high binding energy, such as silicon dioxide, an element having a relatively large mass, such as arsenic (As), may be ion-implanted to break the binding. In order to secure the characteristics of the selector layer 123, it may be required to uniformly distribute the dopants in the insulating layer. However, to uniformly distribute an element having a large mass such as arsenic (As) in the insulating layer, high ion implantation energy may be required and such high ion implantation energy may damage the selector layer 123.

Some implementations of the disclosed technology provide a selector layer capable of preventing and/or reducing damage to the selector layer by not using excessively high ion implantation energy while uniformly distributing dopants in the selector layer to ensure the characteristics of the selector layer by, and a method for providing the selector layer.

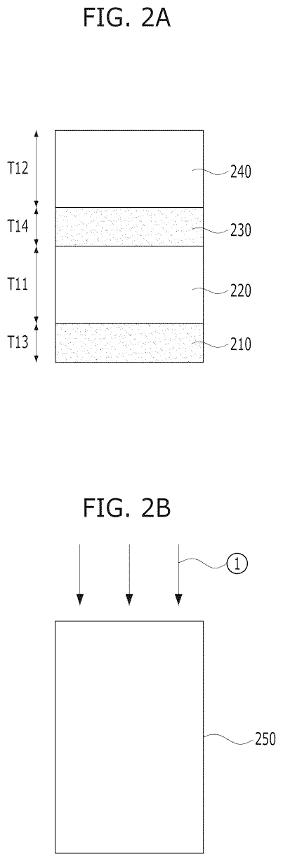

FIGS. 2A and 2B are cross-sectional views illustrating a selector layer and a method for forming the same according to a first embodiment of the present disclosure.

Referring to FIG. 2A, a first adhesive layer 210, a porous layer, 220, a second adhesive layer 230, and an insulating layer 240 may be sequentially formed over a lower structure (not shown) such as an electrode layer.

The insulating layer 240 may be a layer that functions as a selector when trap sites functioning as a movement path for conductive carriers is created in the insulating layer 240 due to dopants doped into the insulating layer 240. The insulating layer 240 may include a silicon-containing insulating material such as silicon oxide, silicon nitride, or silicon oxynitride, an insulating metal oxide, an insulating metal nitride, or a combination thereof. In an example, the insulating layer 240 may include silicon dioxide (SiO₂). The thickness of the insulating layer 240 is indicated as T12.

The porous layer 220 may perform a function of absorbing dopants to be doped during the subsequent ion implantation process and uniformly distributing them in a layer formed as a result of the ion implantation process, that is, the selector. Thus, in the example, the porous layer 220 may act as a dopant absorber or a sponge. The porous layer 220 may be a layer having a porous characteristic compared to the insulating layer 240, and may include carbon (C). Furthermore, the porous layer 220 may further include boron (B), nitrogen (N), or the like, in addition to carbon (C). As an example, the porous layer 220 may be a carbon layer. The thickness of the porous layer 220 is indicated as T11.

The first adhesive layer 210 may serve to improve adhesive properties between a lower structure (not shown) and the porous layer 220, and the second adhesive layer 230 may serve to improve adhesive properties between the porous layer 220 and the insulating layer 240. The first adhesive layer 210 and the second adhesive layer 230 may be selectively formed. For example, at least one of the first adhesive layer 210 and the second adhesive layer 230 may be omitted. The first adhesive layer 210 and the second adhesive layer 230 may each independently include various materials including non-conductive elements, such as SiB, SiCN, SiO₂, SiN, SiBN, or a combination thereof. By including a non-conductive element for the first and second adhesive layers 210 and 230, even when the non-conductive elements of the first and second adhesive layers 210 and 230 are present in the selector, which is formed as a result of the subsequent ion implantation process, the non-conductive elements do not involve or interrupt the operation of the selector. In an example, the first and second adhesive layers 210 and 230 may include silicon nitride (SiN). The thickness of the first adhesive layer 210 is indicated as T13, and the thickness of the second adhesive layer 230 is indicated as T14.

The thickness T11 of the porous layer 220 and the thickness T12 of the insulating layer 240 may be the same or similar to each other. In an example, the thickness T11 of the porous layer 220 to the thickness T12 of the insulating layer 240 may range from 40:60 to 60:40. The thickness T13 of the first adhesive layer 210 may be smaller than each of the thickness T11 of the porous layer 220 and the thickness T12 of the insulating layer 240. The thickness T14 of the second adhesive layer 230 may be smaller than each of the thickness T11 of the porous layer 220 and the thickness T12 of the insulating layer 240. The thickness T13 of the first adhesive layer 210 and the thickness T14 of the second adhesive layer 230 may be the same as or different from each other.

Referring to FIG. 2B, dopants may be doped by performing an ion implantation process (see arrow \textcircled{1}) on the process result of FIG. 2A. The dopants may include an element capable of forming trap sites in the insulating layer 240. For example, when the insulating layer 240 includes silicon dioxide, the dopants may include arsenic. This ion implantation process may be repeated several times.

During this ion implantation process, the first adhesive layer 210, the porous layer 220, the second adhesive layer 230, and the insulating layer 240 may all be mixed to form one layer, and the dopants may exist in this layer. As a result, a layer 250 including constituent elements of the first adhesive layer 210, the porous layer 220, the second adhesive layer 230, and the second insulating layer 240 as well as the dopants may be formed. The layer 250 may function as a selector because it includes trap sites created by breaking bonds between constituent elements of the insulating layer 240 by the dopants. The layer 250 will be referred to as a selector layer 250 hereinafter.

When the first and second adhesive layers 210 and 230 include silicon nitride, the porous layer 220 includes a carbon layer, the insulating layer 240 includes silicon dioxide, and the dopants include arsenic, the selector layer 250 may include oxygen, nitrogen, silicon, carbon, and arsenic.

According to this embodiment, the following advantages may be obtained compared to a comparative example. For reference, the comparative example may correspond to a case in which a selector is formed by forming a stacked structure of an adhesive layer and an insulating layer over a lower structure, for example, an electrode layer, and then performing an ion implantation process on the stacked structure. In the comparative example, there is no structure corresponding to the porous layer 220 of the embodiment as shown in FIG. 2A.

In this embodiment, since the porous layer 220 serves to absorb the dopants, the dopants may be more uniformly distributed in the selector layer 250 under the same ion implantation process as in the comparative example. For example, assuming that the ion implantation is performed with the same number and the energy level in the embodiment of the disclosed technology and the comparative example, the dopants can be distributed in more uniform manner in the embodiment of the disclosed technology as compared to the comparative example. With the more uniform distribution of the dopants in the selector layer 250, the operating characteristics of the selector layer 250, for example, the TS rate, which means the number of normally operating selectors among 100 selectors, can be improved. The improvement in the TS rate has been confirmed experimentally, which will be described later.

In this embodiment, since the porous layer 220 serves to absorb the dopants, the dopant content in the selector layer 250 can be increased compared to the comparative example. As the dopant content increases, the number of generated trap sites increases, so a current can flow easily even if the thickness of the selector layer 250 increases. Accordingly, compared to the comparative example, restrictions on the thickness of the selector layer 250 may be alleviated, and the thickness increase may be facilitated. When the thickness of the selector layer 250 is increased, the forming process may be facilitated and the operation may be stable. In an example, the content of the dopants, such as arsenic, in the selector layer 250 may be in the range of 20 atomic % to 30 atomic %, whereas the content of arsenic in the selector layer of the comparative example may be less than 20 atomic % or less than 10 atomic %. This increase in the dopant content has been also confirmed experimentally, which will be described later.

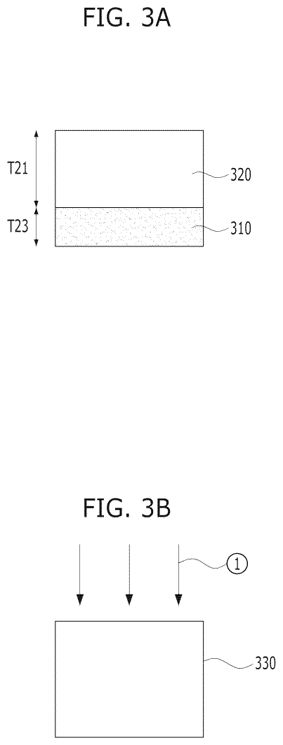

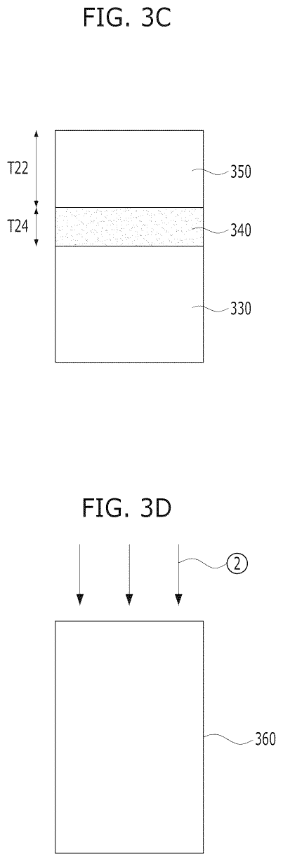

FIGS. 3A to 3D are cross-sectional views illustrating a method for forming a selector layer according to a second embodiment of the present disclosure. Differences from the above-described first embodiment will be mainly described.

Referring to FIG. 3A, a first adhesive layer 310 and a porous layer 320 may be sequentially formed over a lower structure (not shown) such as an electrode layer. The thickness of the porous layer 320 is indicated as T21, and the thickness of the first adhesive layer 310 is indicated as T23.

Referring to FIG. 3B, dopants may be doped by performing a first ion implantation process (see arrow \textcircled{1}) on the process result of FIG. 3A.

During the first ion implantation process, the first adhesive layer 310 and the porous layer 320 may be mixed to form one layer, and the dopants may exist in this layer. As a result, a first layer 330 including the dopants and constituent elements of the first adhesive layer 310 and the porous layer 320 may be formed. When the first adhesive layer 310 includes silicon nitride, the porous layer 320 includes a carbon layer, and the dopants include arsenic, the first layer 330 may include nitrogen, silicon, carbon, and arsenic.

Since this first ion implantation process is performed in a state in which the first adhesive layer 310 and the porous layer 320 are formed, ions may be easily transferred to the electrode layer below the first adhesive layer 310 compared to the first embodiment described above where the ions are provided from the location further away from the electrode layer due to the additional layers including the second adhesive layer 230 and the insulating layer 240. As a result, constituent elements of the electrode layer may be mixed into the first layer 330. As an example, when the electrode layer includes titanium nitride (TiN), the first layer 330 may further include titanium (Ti), which is a constituent element of the electrode layer.

Referring to FIG. 3C, a second adhesive layer 340 and an insulating layer 350 may be sequentially formed over the first layer 330. The thickness of the insulating layer 350 is indicated as T22, and the thickness of the second adhesive layer 340 is indicated as T24.

Referring to FIG. 3D, dopants may be doped by performing a second ion implantation process (see arrow \textcircled{2}) on the process result of FIG. 3C. In some implementations, the dopants doped during the second ion implantation process may be the same as the dopants doped during the first ion implantation process. In some implementations, the dopants during the second ion implantation process may be different from the dopants doped during the first ion implantation process as long as the dopants during the first ion implantation process and the dopants during the second ion implantation process can break the bond between the constituent elements of the insulating layer.

During the second ion implantation process, the first layer 330, the second adhesive layer 340, and the insulating layer 350 may be mixed to form one layer, and the dopants doped during the first and second ion implantation processes may exist in this layer. As a result, a layer 360 including constituent elements of the first layer 330, the second adhesive layer 340, and the insulating layer 350 as well as the dopants doped during the first and second ion implantation processes may be formed. The layer 360 may function as a selector because it includes trap sites created by breaking bonds between constituent elements of the insulating layer 350 by the dopants doped during the first and second ion implantation processes. The layer 360 will be referred to as a selector layer 360 hereinafter.

When the first layer 330 includes nitrogen, silicon, carbon, and arsenic, the second adhesive layer 340 includes silicon nitride, the insulating layer 350 includes silicon dioxide, and the dopants include arsenic, the selector layer 360 may include oxygen, nitrogen, silicon, carbon, and arsenic. Furthermore, when the first layer 330 further includes, for example, titanium, a constituent element of an electrode layer disposed below the first layer 330, the selector layer 360 may further include titanium.

Each of the first ion implantation process and the second ion implantation process may be performed once or may be repeatedly performed several times.

According to this embodiment, the above-described effects of the first embodiment may be obtained. Furthermore, by dividing the ion implantation process into first and second steps, the dopants in the selector layer 360 may be more uniformly distributed. Accordingly, the characteristics of the selector layer 360, for example, the TS rate, may be further improved.

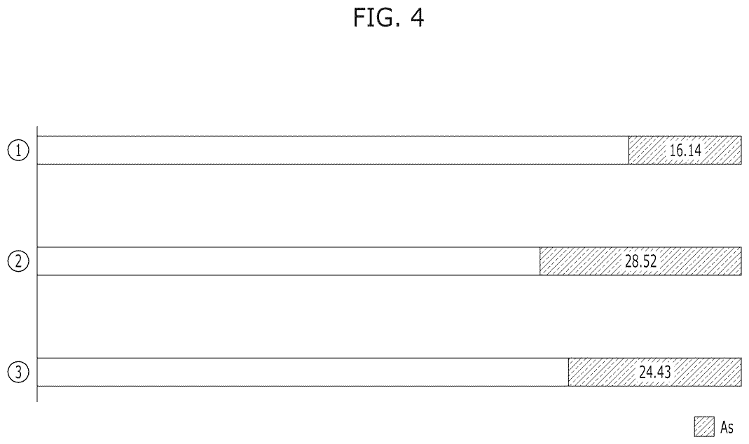

FIG. 4 is a view illustrating a content of constituent elements of a selector layer. More specifically, a first case (see \textcircled{1}) substantially corresponds to the comparative example, and shows a content of constituent elements of a selector layer formed by forming a silicon nitride adhesive layer and a silicon oxide insulating layer over a TiN electrode layer, and performing an arsenic ion implantation process. The second case (see \textcircled{2}) substantially corresponds to the first embodiment as described with regard to FIGS. 2A and 2B, and shows a content of constituent elements of a selector layer formed by forming a silicon nitride adhesive layer, a carbon layer, a silicon nitride adhesive layer, and a silicon oxide insulating layer over a TiN electrode layer, and performing an arsenic ion implantation process. The third case (see \textcircled{3}) substantially corresponds to the second embodiment as described with regard to FIGS. 3A to 3D, and shows a content of constituent elements of a selector layer formed by forming a silicon nitride adhesive layer and a carbon layer over a TiN electrode layer, performing a first arsenic ion implantation process, forming a silicon nitride adhesive layer and a silicon oxide insulating layer, and performing a second arsenic ion implantation process. In the first case, the second case, and the third case, energy and dose of the arsenic ion implantation process may be the same. Assuming that the ion implantation process is performed N times in each of the first case and the second case, the sum of the number of times of the ion implantation process during the first ion implantation process and the number of times of the ion implantation process during the second ion implantation process in the third case may be N. For example, if ion implantation processes are performed 4 times in each of the first case and the second case, ion implantation processes may be performed two times during the first ion implantation process and two times during the second ion implantation process in the third case.

Referring to FIG. 4, in the first case, the content of arsenic in the selector layer is 16.14. On the other hand, in the second case, the arsenic content in the selector layer is 28.52, and in the third case, the arsenic content in the selector layer is 24.43. That is, it may be seen that the content of arsenic is further increased in the second and third cases compared to the first case.

As a result, it may be confirmed that when a porous layer such as a carbon layer is used, the content of the dopants is increased in the selector layer.

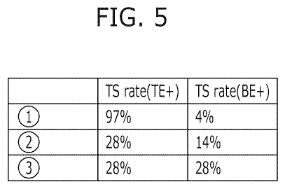

FIG. 5 is a view illustrating a characteristic of a selector layer. In this figure, the first case (\textcircled{1}), the second case (\textcircled{2}), and the third case (\textcircled{3}) may be the same as those described in FIG. 4 above.

Referring to FIG. 5, in the first case, the TS rate when a relatively positive voltage is applied to the electrode layer located on the selector layer is 97%, but the TS rate when a relatively positive voltage is applied to the electrode layer located below the selector layer is 4%. Thus, it may be seen that the difference in the TS rate is very large depending on which electrode layer is applied with the positive voltage. This may mean that arsenic is not uniformly distributed in the selector layer.

In the second case, the TS rate when a relatively positive voltage is applied to the electrode layer located on the selector layer is 28%, and the TS rate when a relatively positive voltage is applied to the electrode layer located below the selector layer is 14%. Thus, it may be seen that the difference in the TS rate is remarkably reduced compared to the first case. This may mean that arsenic is uniformly distributed in the selector layer.

In the third case, the TS rate when a relatively positive voltage is applied to the electrode layer located on the selector layer is 28%, and the TS rate when a relatively positive voltage is applied to the electrode layer located below the selector layer is 28%. Thus, it may be seen that the difference in the TS rate is more remarkably reduced compared to the first case. This may mean that arsenic is more uniformly distributed in the selector layer.

Compared to the first case, while the TS rate is improved in the second and third cases, other characteristics of the selector layer may be substantially maintained. For example, it may be confirmed that, in the first to third cases, the forming voltage (Vf) for initially creating the conductive path in the selector layer, the threshold voltage (Vth) of the selector layer, the on-resistance (Ron) of the selector layer, or the like, are at similar levels to each other.

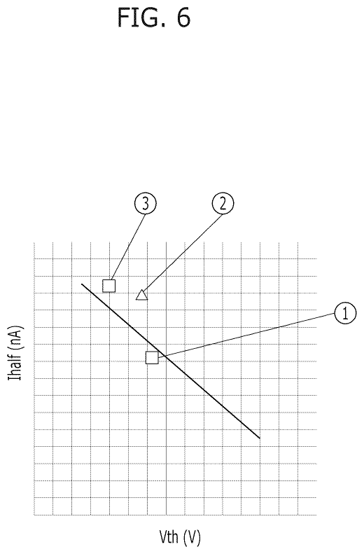

FIG. 6 is a view illustrating a half current according to a threshold voltage of a selector layer. The half current may show leakage current of the selector layer. If the half current is relatively high, the leakage current is relatively large, and if the half current is relatively low, the leakage current is relatively low. In this figure, the first case (\textcircled{1}), the second case (\textcircled{2}), and the third case (\textcircled{3}) may be the same as those described in FIG. 4 above.

Referring to FIG. 6, it can be seen that when a straight line showing a half current decreasing trend according to an increase in threshold voltage exists, the first case, the second case, and the third case are all positioned adjacent to the straight line. This shows that the first to third cases all have similar half currents, that is, leakage currents.

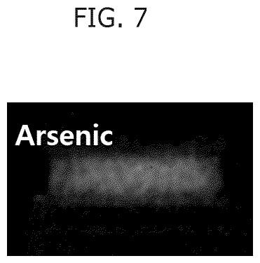

FIG. 7 is a photograph illustrating arsenic distribution in a selector layer. FIG. 7 is a photograph of the selector layer manufactured by the third case of FIG. 4 described above.

Referring to FIG. 7, in the third case, it can be seen that arsenic is uniformly distributed in the selector layer.

In summary, referring to the data of FIGS. 4 to 7, compared to the first case corresponding to the comparative example, in the second and third cases corresponding to the present embodiments, the arsenic content of the selector layer is increased while the arsenic is uniformly distributed. Furthermore, other characteristics of the selector layer in the second and third cases, such as a forming voltage, a threshold voltage, an on-resistance, and a leakage current, may be maintained at levels similar to those in the first case. That is, it can be seen that the effects described in the first embodiment of FIGS. 2A and 2B and the second embodiment of FIGS. 3A and 3B are supported by the data.

According to the above embodiments of the present disclosure, it may be possible to improve a characteristic of a selector.

Although various embodiments have been described for illustrative purposes, it will be apparent to those skilled in the art that various changes and modifications may be made based on the disclosure in this patent document.

What is claimed is:

1. A semiconductor device comprising:
a plurality of memory cells, wherein each memory cell comprises:
a memory layer configured to store data; and
a selector layer configured to control an access to the memory layer,
wherein the selector layer includes a layer which includes an insulating material and a porous material that are mixed, and a dopant that is present in the layer and breaks a bond between constituent elements of the insulating material.

2. The semiconductor device according to claim 1, wherein the porous material includes carbon.

3. The semiconductor device according to claim 2, wherein the insulating material includes silicon dioxide, and the dopant includes arsenic.

4. The semiconductor device according to claim 1, wherein the layer included in the selector layer further includes an adhesive material mixed with the insulating material and the porous material.

5. The semiconductor device according to claim 4, wherein the adhesive material includes silicon nitride.

6. The semiconductor device according to claim 1, wherein each of the memory cells further comprises:
an electrode layer disposed under the selector layer and configured to provide a passage through which a voltage or current passes,
wherein the selector layer further includes a constituent element of the electrode layer.

7. The semiconductor device according to claim 6, wherein the constituent element of the electrode layer includes titanium.

8. The semiconductor device according to claim 1, further comprising:
a plurality of first conductive lines extending in a first direction; and
a plurality of second conductive lines extending in a second direction crossing the first direction,
wherein the plurality of memory cells are respectively disposed between the plurality of first conductive lines and the plurality of second conductive lines to overlap intersection regions of the plurality of first conductive lines and the plurality of second conductive lines.

9. A method for fabricating a semiconductor device, comprising:
forming a memory layer configured to store data; and
forming a selector layer for controlling an access to the memory layer,
wherein the forming of the selector layer comprises:
forming a porous layer;
forming an insulating layer over the porous layer; and
performing an ion implantation to implant a dopant into the porous layer and the insulating layer, wherein the dopant is capable of breaking a bond between constituent elements of the insulating layer.

10. The method according to claim 9, wherein the porous layer includes carbon.

11. The method according to claim 10, wherein the insulating layer includes silicon dioxide, and the dopant includes arsenic.

12. The method according to claim 9, wherein a thickness of the insulating layer to a thickness of the porous layer is in a range of 40:60 to 60:40.

13. The method according to claim 9, further comprising:
forming an adhesive layer under the porous layer before the forming of the porous layer or under the insulating layer before the forming of the insulating layer.

14. The method according to claim 13, wherein the adhesive layer includes silicon nitride.

15. The method according to claim 13, wherein a thickness of the adhesive layer is smaller than a thickness of the porous layer and a thickness of the insulating layer.

16. A method for fabricating a semiconductor device, comprising:
forming a memory layer configured to store data; and
forming a selector layer for controlling an access to the memory layer,
wherein the forming of the selector layer comprises:
forming a porous layer;
performing a first ion implantation to implant a first dopant into the porous layer;
forming an insulating layer over the porous layer; and
performing a second ion implantation to implant a second dopant into the porous layer and the insulating layer, wherein the first and second dopants are capable of breaking a bond between constituent elements of the insulating layer.

17. The method according to claim 16, wherein the porous layer includes carbon.

18. The method according to claim 17, wherein the insulating layer includes silicon dioxide, and the first dopant and the second dopant include arsenic.

19. The method according to claim 16, wherein a thickness of the insulating layer to a thickness of the porous layer is in a range of 40:60 to 60:40.

20. The method according to claim 16, further comprising:
forming an adhesive layer under the porous layer before the forming of the porous layer or under the insulating layer before the forming of the insulating layer.

21. The method according to claim 20, wherein the adhesive layer includes silicon nitride.

22. The method according to claim 20, wherein a thickness of the adhesive layer is smaller than a thickness of the porous layer and a thickness of the insulating layer.
